(19) United States
(12) Patent Application Publication
(10) Pub. No.: US 2022/0307138 A1
(43) Pub. Date: Sep. 29, 2022

(54) REACTOR FOR GAS TREATMENT OF A SUBSTRATE

(71) Applicant: SweGaN AB, Linkoping (SE)

(72) Inventors: Olof Kordina, Linkoping (SE); Jr-Tai Chen, Vikingstad (SE); Martin Eriksson, Klockrike (SE)

(21) Appl. No.: 17/617,921

(22) PCT Filed: Jun. 10, 2019
(86) PCT No.: PCT/EP2019/065080

§ 371 Date: Dec. 9, 2021

(51) Int. Cl. C23C 16/455; C30B 25/14; B01F 23/10; B01F 25/25; B01F 25/433

(52) U.S. Cl. CPC C23C 16/45591; C23C 16/45504; C23C 16/45565; C23C 16/45574; C23C 16/45582; C30B 25/14; B01F 23/10; B01F 25/25; B01F 25/4336; B01F 2101/58

(57) ABSTRACT

The present document discloses a gas inlet device (21, 21a-21k) for use in a reactor for gas treatment of a substrate. The gas inlet device comprises an inlet niche having a back wall (233), and a side wall (234, 235) extending in a downstream direction (F) from the back wall (233) towards an inlet niche opening (212), an impingement surface (243), a gas orifice (210), which is configured to direct a gas flow towards the impingement surface (243), and a taper surface (244, 245), extending downstream of the impingement surface (243), such that a flow gap (213) having, along the downstream direction (F), gradually increasing cross sectional area, is formed between the side wall (234, 235) and the taper surface (244, 245).

The document further discloses a mixing device, a gas outlet device a reactor and the use of such reactor.

### TECHNICAL FIELD

The present disclosure relates to a reactor for gas treatment of a substrate, such as by chemical vapor deposition (“CVD”), e.g. in order to form epitaxial layers on a semiconductor material substrate.

The disclosure further relates to a method of gas treatment of a substrate, in which the reactor may be used.

### BACKGROUND

In reactors for gas treatment of substrates, such as CVD reactors used for creating epitaxial layers on semiconductor material substrates, it is desirable to achieve uniform material distribution and properties throughout the epitaxial layer.

One strategy for achieving this objective is to make sure that the process gases are distributed evenly over the reaction chamber, as disclosed in US2011277690AA, wherein a plurality of gas inlets are provided as a m×n (vertical×horizontal) array of gas inlets.

Another strategy is to achieve a laminar flow. It is well known that for a laminar flow to form, sudden increases in flow area are to be avoided. It is known from e.g. US2015167161AA to provide each gas inlet with an outlet portion, a flow area of which increases gradually.

In addition to the challenges discussed above, it is desirable to provide a reactor which is more compact, which has better performance and which is preferably less costly to manufacture.

Hence, there is a need for an improved reaction chamber.

### SUMMARY

A general objective of the present disclosure is to provide an improved reaction chamber that is useful for CVD treatment of substrates. A particular object is to provide a reaction chamber which provides improved uniformity of gas flow and of gas distribution in the reaction chamber.

The invention is defined by the appended independent claims, with embodiments being set forth in the dependent claims, in the following description and in the enclosed drawings.

According to a first aspect, there is provided a gas inlet device for use in a reactor for gas treatment of a substrate, comprising an inlet niche having a back wall, and a side wall extending in a downstream direction from the back wall towards an inlet niche opening, an impingement surface, a gas orifice, which is configured to direct a gas flow towards the impingement surface, and a taper surface, extending downstream of the impingement surface, such that a flow gap having, along the downstream direction, gradually increasing cross sectional area, is formed between the side wall and the taper surface.

An “impingement surface” is a surface towards which the flow of gas is directed, such that the gas flow will change direction and diffuse.

The impingement surface may be parallel with the back wall.

The “downstream direction” is defined as a direction along which the gas flows.

Allowing the gas flow to impinge on a surface, causes it to change direction before entering into the flow gap, which enhances distribution of the gas over the flow gap. Then allowing the gas to flow along a taper surface will bring back the gas to a laminar flow, such that turbulence is reduced.

The impingement surface may be perpendicular±10 degrees, preferably ±5 degrees or ±1 degree, to the gas flow directed by the gas orifice.

A gas orifice opening may be flush with the back wall, or even recessed into the back wall.

Alternatively, a gas orifice opening may extend out of back wall towards the impingement surface.

The impingement surface may present a recess.

The recess may be of any shape. For example, the recess may be cylindrical or concave in shape. Moreover, the recess may extend over part or all of the impingement surface.

The gas orifice may extend into the recess.

The gas flow directed by the gas orifice may be directed towards a geometric center of gravity of the impingement surface.

The taper surface may extend at a taper angle of less than 8 degrees to the downstream direction.

An innermost end of the taper surface may intersect the impingement surface.

A longitudinal surface may extend between the taper surface and the impingement surface, the longitudinal surface extending at an angle to the downstream direction which is less than a taper angle of the taper surface.

For example, the longitudinal surface extending between the taper surface the impingement surface may extend at an angle of 0-6 degrees, preferably 0-4 degrees, 0-2 degrees or 0 degrees relative to the downstream direction.

The side wall may extend at an angle to the downstream direction which is less than a taper angle of the taper surface.

For example, the side wall may extend at an angle of 0-6 degrees, preferably 0-4 degrees, 0-2 degrees or 0 degrees relative to the downstream direction.

The the side wall may present an upstream portion and a downstream portion, and the downstream portion may extend at a greater angle to the downstream direction than the upstream portion.

The gas inlet device as claimed in any one of the preceding claims, further comprising a throttling arrangement, which is configured such that a gas flow of the gas inlet is adjustable between a maximum flow and a minimum flow.

The throttling arrangement may comprise any type of valve that is capable of adjusting the gas flow, either in steps or continuously, between the maximum flow and the minimum flow. One example of such a valve is a needle valve. As another example, a mass flow controller (“MFC”) may be used. As yet another option, a position of the impingement surface relative to the gas orifice may be used as a throttling device. The minimum flow may be zero.

The niche may present a pair of opposing walls and wherein the taper surface and the side wall extend completely between said opposing walls.

That is, the taper surface and the side wall may be effectively sealed against the opposing walls, such that the flow gap is formed by the taper surface, the side wall and the opposing walls.

The flow gap may present a rectangular cross section, defined by the opposing walls, the taper surface and the side wall.

The gas inlet device may be formed by the niche and a wedge member, which is received in the niche, such that a short side of the wedge member provides the impingement surface.

The niche may present a pair of side walls, and the wedge member may be spaced from both side walls, such that flow gaps are formed on both sides of the wedge member.

The gas inlet device as claimed in claim 16 or 17, wherein the wedge member presents a pair of taper surfaces, both of which extend at a taper angle of less than 8 degrees to the downstream direction (F).

Hence, one flow gap is defined by one of the taper surfaces and one of the side surfaces and another flow gap is defined by the other one of the taper surfaces and the other one of the side surfaces.

The inlet wedge member may be formed as a right prism having a base surface defined by a broad side and a pair of taper sides.

The opposing surfaces may be horizontally arranged±30 degrees, preferably ±10 degrees, ±5 degrees or ±1 degree.

Hence, the flow gap may taper towards one lateral direction.

A horizontal wall is a wall that extends substantially horizontally. For the purpose of this disclosure “horizontally” should be interpreted as extending at an angle to a vertical direction of 90±10 degrees, preferably 90±5 degrees or 90±1 degree.

Alternatively, the taper surface and the side surface may be vertically arranged±30 degrees, preferably ±10 degrees, ±5 degrees or ±1 degree.

Hence, the flow gap may taper upwardly or downwardly.

That is, the flow gap provides a flow area on a lateral side of the wedge member, such that gas can flow past the wedge member.

Hence, the gas orifice may open approximately halfway between the horizontal walls, and approximately halfway between the vertical walls.

The niche may present at least two juxtaposed side wall portions that extend at an angle to each other of 50-150 degrees, preferably 90-120 degrees, and at least two juxtaposed taper surfaces, which extend at an angle to each other of 50-150 degrees, preferably 90-120 degrees.

The gas inlet device may be formed by the niche and a wedge member, which is received in the niche, such that a short side of the wedge member provides the impingement surface.

The side wall may surround the taper surface, and, as seen in cross section perpendicular to the downstream direction, the side wall and the wedge member have the same shape but different sizes and are coaxially arranged, such that the flow gap surrounds the wedge member.

The side wall and the wedge member may be formed as curved-cross section bodies, such as ovals, ellipses or circles.

Consequently, the wedge member will preset a conical portion.

The side wall and the wedge member may be formed as polygons, which are preferably triangular, rectangular, square or hexagonal.

According to a second aspect, there is provided a mixing device for use in a reactor for gas treatment of a substrate, comprising a body having an upstream portion and a downstream portion, wherein the upstream portion presents a convex surface facing towards the upstream an, and wherein the downstream portion tapers in a downstream direction, towards an edge formed at a downstream end of the body.

A mixing device can be arranged in the flowpath between a gas inlet device and a substrate that is to be treated. The elongate shape and tapering form of the mixing device will act so as to cause gas passing the mixing device on one side there of to better mix with gas passing the mixing device on the other side of the mixing device, with a minimum of turbulence. Hence, the mixing device can be used to provide a gentle mixing of gas introduced by a gas inlet device as disclosed herein.

The body may present a constant cross section along a direction that is transverse, preferably perpendicular, to the downstream direction.

The cross section may be symmetric about a plane that is parallel with the downstream direction.

The cross section may be elongate and substantially drop shaped.

According to a third aspect, there is provided a gas inlet array comprising a plurality of m×n gas inlet devices as described above, wherein m≥1 and n≥2.

A number of gas inlets provided in a vertical direction may be less than 5, preferably 1 or 2.

A number of gas inlets provided in a horizontal direction may be an odd number, preferably less than 30, less than 20 or less than 15. Specific preferred numbers may be 7, 9, 11 and 13.

A pair of juxtaposed gas inlets may be separated by a divider wall, which forms a wall of each of the pair of juxtaposed inlets, and the divider wall may have a cross section, a portion of which tapers in the downstream direction.

The divider wall may have a first portion, which is non-tapering and a second portion, which is tapering.

The divider wall may present at least one taper surface, which extends at a taper angle of less than 8 degrees to the downstream direction.

The gas inlet array may further comprise a plurality of mixing devices as described above, wherein each mixing device is aligned with at least one of the gas inlet devices.

Hence, the number of mixing devices may be equal to the number of gas inlet devices.

Alternatively, in each direction (horizontal or vertical), the number of mixing devices may be one greater than or one less than the number of gas inlet devices arranged in the respective direction, i.e. m+/−1 and n+/−1.

Each of the mixing devices may be aligned with a center, as seen in a direction perpendicular to the downstream direction, of an inlet niche.

Each of the mixing devices may be aligned with a divider wall, which separates a pair of adjacent gas inlet devices.

The mixing devices may be spaced in the downstream direction from the respective gas inlet device. The spacing may be on the order of 30%-200%, preferably 50%-100% of a total length of the mixing device, as seen along the downstream direction.

The alignment may be in a horizontal direction, in the case where the mixing device body has a constant cross section in a vertical direction.

Alternatively, the alignment may be in a vertical direction, in the case where the mixing device body has a constant cross section in a horizontal direction.

The mixing device may extend all the way between a pair of opposing walls, which delimit the inlet niche.

That is, the mixing device may extend vertically between a niche bottom and a niche top surface. Alternatively, the mixing device may extend horizontally between a pair of niche side walls.

According to a third aspect, there is provided a gas outlet device for use in a reactor for gas treatment of a substrate, comprising an upstream portion having a first flow area which is sized and adapted to correspond to a flow area of a gas treatment portion of the reactor, a downstream portion, having a smaller second flow area than the upstream portion, and a transition portion, connecting the upstream portion and the downstream portion, and having a gradually diminishing flow area.

The upstream portion may provide a first flow direction, which is substantially parallel with a flow direction in the reactor, and the downstream portion may provide a second flow direction which presents an angle of 30-90 degrees, preferably 60-90 degrees, to the first flow direction.

In the transition portion, a flow area width can be approximated by the expression W_{F}=Wᵢₙᵢₜ−2×I_{F} tan(γ), wherein Wᵢₙᵢₜ is the width at the upstream portion of the gas outlet device, I_{F} is a length from an upstream start of the transition portion, and γ is a taper angle of the flow area in the transition portion, and wherein, in the transition portion, the width diminishes by less than twice the length I_{F}.

The upstream portion may comprise a feed opening, which provides a straight path from an exterior hatch to the gas treatment portion of the reactor.

The transition portion may extend at an angle, as seen in a vertical plane, of 70-90 degrees, preferably 80-90 degrees, to the upstream portion.

According to a fourth aspect, there is provided a reactor for gas treatment of a substrate, in particular for forming an epitaxial layer through a chemical vapor deposition process, comprising a gas inlet array as described above, and/or a gas outlet device as described above.

The reactor may further comprise a substrate table, which is configured to hold the substrate with an orientation such that a gas flow direction at the substrate is parallel with a substrate surface, said substrate table optionally being rotatable about an axis perpendicular to a substrate main plane.

The inlet array may present a major direction and a minor direction, and wherein the substrate table is configured to hold the substrate with its substrate surface parallel with the major direction.

The gas inlet devices may be arranged with their downstream directions parallel with each other.

The gas inlet devices may be arranged with their downstream directions extending radially with a common center.

The gas inlet devices may be arranged at a center of the reactor with the downstream directions extending radially outwardly and the substrate tables may be arranged radially outwardly of the gas inlet devices.

The gas inlet devices may be arranged at a periphery of the reactor with the downstream directions extending radially inwardly and the substrate tables may be arranged radially inwardly of the gas inlet devices.

The reactor may further comprise a reaction chamber and a heater, for heating at least an area of the reaction chamber, in which the substrate is positioned during treatment.

The heater may be a resistive heater, having resistive heating elements on both main sides of the substrate.

The reactor may have an upstream end, at which the gas inlet array is arranged, and a downstream end, arranged on an opposite side of the substrate, as seen in the downstream direction.

As an alternative, the reactor may comprise a substrate table, which is configured to hold the substrate with an orientation such that the gas inlet array is positioned with downstream directions of the gas inlet devices substantially perpendicular to a substrate surface, said substrate table optionally being rotatable about an axis perpendicular to a substrate main plane.

According to a fifth aspect, there is provided use of a reactor as described above for forming an epitaxial layer on a semiconductor substrate.

That is, the reactor may be used for chemical vapor deposition (“CVD”) of semiconductor type substrates, such as silicon, silicon carbide, gallium nitride, etc.

In a preferred use, only one reactive gas is introduced into the reactor through each gas inlet device.

Optionally, at least two reactive gases are introduced by respective first and second gas inlet devices.

It is noted that each reactive gas may be introduced by a plurality of inlet devices. In such situation, a pair of inlet devices introducing the same gas may be separated by at least one inlet device introducing another gas.

A shield gas may be introduced by a third gas inlet device, which may be sandwiched between the first and second gas inlet devices.

The sandwiching may be achieved in one or more directions of an array of gas inlet devices.

The gas inlet design and mixing device disclosed herein find general application in the CVD processing of semiconductor substrates, and in particular in such processing where use is made of process gases which are prone to reacting with each other, such as would be the case when producing gallium oxide layers from a gallium source (e.g. TMGa) and oxygen.

### BRIEF DESCRIPTION OF THE DRAWINGS

FIG. 1a is a schematic perspective view of a CVD reactor.

FIG. 1b is a schematic planar view of the CVD reactor.

FIG. 2 is a schematic planar view of an inlet portion of the CVD reactor.

FIG. 3 is a detail view of a part of the inlet portion.

FIGS. 4a-4d schematically illustrate an inlet wedge according to a first embodiment.

FIGS. 5a-5e schematically illustrate an inlet wedge according to a second embodiment.

FIG. 6 schematically illustrates the invention in a broad sense.

FIGS. 7a-7b schematically illustrate a gas inlet and gas inlet arrays according to a first embodiment.

FIGS. 8a-8c schematically illustrate a gas inlet and gas inlet arrays according to a second embodiment.

FIGS. 9a-9b schematically illustrate a gas inlet and gas inlet array according to a third embodiment.

FIG. 10 is a schematic detail view of a portion of the reactor 1, focusing on the outlet device.

FIGS. 11a-11b schematically illustrate the loading/unloading access to the reactor.

FIG. 12 schematically illustrates a gas treatment system.

FIG. 13a-13b schematically illustrate a mixing device.

FIG. 14 schematically illustrates an alternative embodiment of the mixing device.

### DETAILED DESCRIPTION

The reactor 1 comprises a reactor casing 10, a gas inlet device 2 and a gas outlet device 3. The gas inlet 2 and gas outlet 3 are arranged on opposite sides of a substrate table 4, such that gas may pass the substrate table 4 on its way from the gas inlet 2 to the gas outlet 3. The substrate table 4 may comprise a substrate holder (not shown), which is configured to prevent the substrate from moving relative to the substrate table during processing in the reactor 1.

For example, the substrate holder may be provided by a recess, which may have a depth which is about 50-150% of a thickness of the substrate. The recess may have a shape that substantially corresponds to a circumferential shape of the substrate.

Alternatively, the substrate holder may comprise one or more protrusions from a table surface. In the illustrated example, a single substrate table 4 is provided at a center of the reactor casing 10. The substrate table 4 is arranged such that the substrate 20 will be horizontally oriented during processing. The substrate table 4 may be rotatable R about an axis that is substantially vertical.

It is noted that in other embodiments, a plurality of substrate tables 4 may be provided. For example, such plurality of substrate tables may be provided in a planetary arrangement, i.e. such that the substrate tables 4 may be caused to move along a predetermined path, which may be closed and in particular oval, elliptic, circular, or the like. To this end, the substrate tables 4 may be mounted on a planet disc, which may be rotatable about a planet axis.

Moreover, each substrate table 4 may be rotatable R about its own axis, which may be centrally located to the substrate table 4. To this end, the substrate tables may be provided as satellite discs, each being rotatable relative to the planet disc.

A drive arrangement (not shown) may be used to cause the planet disc and the satellite discs to rotate. Such drive arrangement may comprise a set of belts and/or gear wheels, such that a single drive source can drive both the planet disc and the satellite discs. Alternatively, one motor may be used to drive the planet disc and another motor may be used to drive the satellite discs. For example, there may be provided one motor for each of the satellite discs.

As yet another alternative, a gas foil rotation (which is known as such) may be used, causing the rotating part to lift slightly and rotate.

The substrate table(s) 4 may be positioned such that a substrate treatment surface, i.e. the surface that is to be subjected to gas treatment, or in the present case, chemical vapor deposition, is parallel to a flow direction F from the gas inlet 2 to the gas outlet 3. In particular, where the gas inlet 2 is provided as a matrix having a major direction and a minor direction, the substrate table 4 may be positioned so as to be parallel with the major direction.

The reactor 1 may further comprise a heating arrangement 5. The heating may, as main options, be inductive or resistive, with a preference for resistive heating due to the fact that it is easier to achieve an even heating in the zone around the substrate table(s) 4.

One or more temperature sensors 6a-6d may be provided in order to monitor the temperature in the reactor. In the present example, pyrometers are primarily contemplated.

Heatable chamber walls 7 may be provided, in the case a hot-wall type reactor is desired. The walls 7 may be formed of graphite, which may be coated, e.g. with TaC (tantalum carbide) or SiC (silicon carbide).

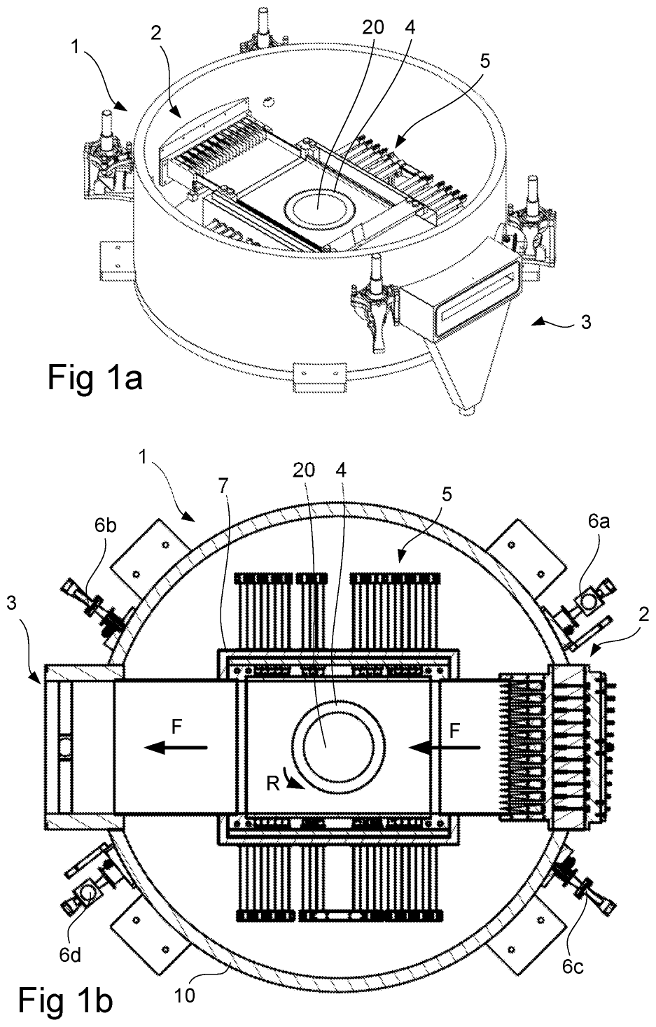

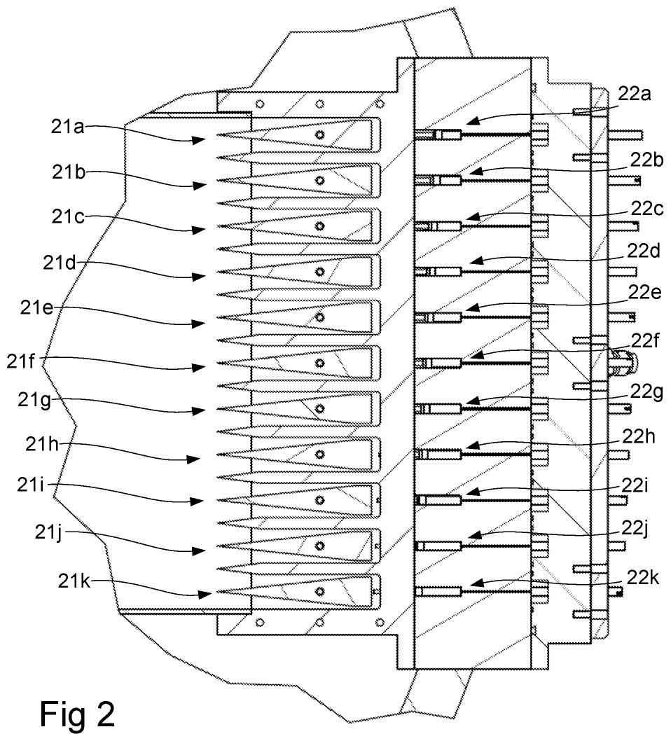

Referring to FIG. 2, there is illustrated an enlarged view of a 1×11 gas inlet array, as used in FIGS. 1a-1b.

In FIG. 2, there is illustrated a plurality of gas inlet devices 21a-21k, which form the gas inlet array. Each gas inlet device 21a-21k is supplied via a respective gas inlet control device 22a-22k.

The gas inlet control devices 22a-22k may be provided in the form of tunable valve, i.e. a valve that may be set to a plurality of different position between a maximum open position and a maximum closed position. One example of such a valve may be a so-called “needle valve”.

In other embodiments, the gas inlet control device 22a-22k may be provided by so-called “mass flow controllers”.

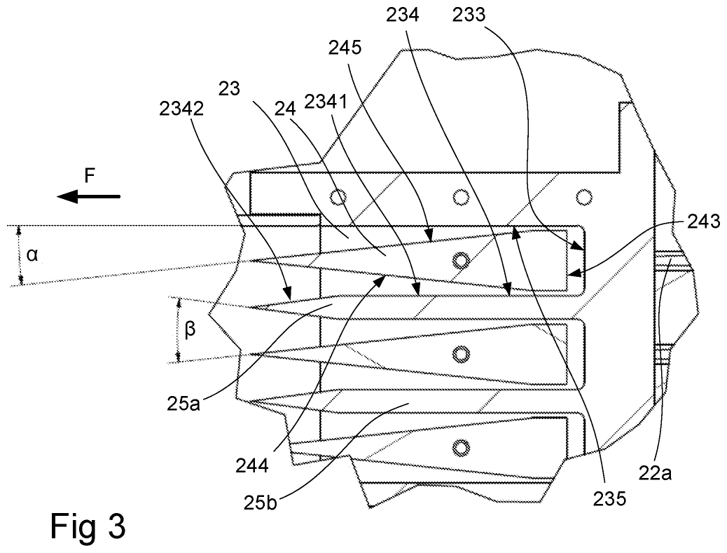

Referring to FIG. 3, there is illustrated a further enlarged view of a portion of the gas inlet array in FIG. 2.

In FIG. 3, there is illustrated a pair of adjacent gas inlets 21a, 21b. Each gas inlet comprises a niche 23, in which a wedge member 24 is received. The niche presents a back wall 233, a bottom wall 236, a top wall 237 and a pair of side walls 234, 235.

The back wall 233 and the side walls 234, 235 may be substantially vertical. The bottom wall 236 and the top wall 237 may be substantially horizontal. Opposite the back wall 233, there is an opening.

The side walls 234, 235, the bottom wall 236 and the top wall 237 extend from the back wall 233 and downstream along the flow direction F towards the opening.

Gas is supplied through an orifice 210, that is connected to the gas inlet control device 22a, and that opens at a niche back wall 233.

The side walls 234, 235 may comprise a first portion 2341, which may be a proximal portion, closest to the back wall 233, which is parallel to the flow direction F, and which may be substantially perpendicular to the back wall 233.

The side walls 234, 235 may further comprise a second portion 2342, which may be a distal portion, furthest away from the back wall 233, which tapers by a taper angle α of less than about 8 degrees, preferably less than about 7 degrees.

The outermost side walls, as seen in the width direction of the array, may not present any tapering portions, provided such outermost side walls are flush with an adjoining downstream flow channel wall, such that no sharp corners are provided that may cause turbulence.

Each pair of adjacent gas inlets 21a, 21b may be separated by a divider wall 25a, 25b. The tapering portions 2342 of the side walls may thus form a vertical downstream edge at each divider wall 25a, 25b.

In each niche 23, there is provided a wedge member 24. The wedge member presents a rear wall 243 and a pair of taper walls 244, 245.

In the illustrated example, the wedge member is formed as a right prism, having a base surface and side surfaces. The side surfaces form the rear wall 243 and the taper walls 244, 245.

The rear wall 243 is positioned substantially parallel with the back wall 233 of the niche 23, and spaced from the back wall 233, such that gas flowing from the orifice 210 impinges on the rear wall 243 of the wedge member 24. Hence, the rear wall 243 forms an impingement surface. Preferably, the orifice should be located at a geometric center of gravity of the rear wall 243. Also preferably, the orifice should provide a flow that is perpendicular to the rear wall 243.

As seen in the width direction of the array (horizontally and perpendicular to the flow direction), the wedge member 24 is centered in its associated niche 23, such that flow gaps are formed on each side of the wedge member 24, between the wedge member 24 and the side walls 234, 235.

The taper walls 244, 245 may present a taper angle α to the flow direction F, which is less than 8 degrees, preferably less than 7 degrees. The taper walls 244, 245 may form a vertical downstream edge at each wedge member.

At the opening of each gas inlet device 21a-21k, an opening angle β between each side wall 234, 234 and its opposing taper wall 244, 245 of the wedge member 24 should be less than 16 degrees, preferably less than 15 degrees, in order to avoid formation of turbulence due to the flow surface enlargement and thereby provided decrease in gas flow velocity.

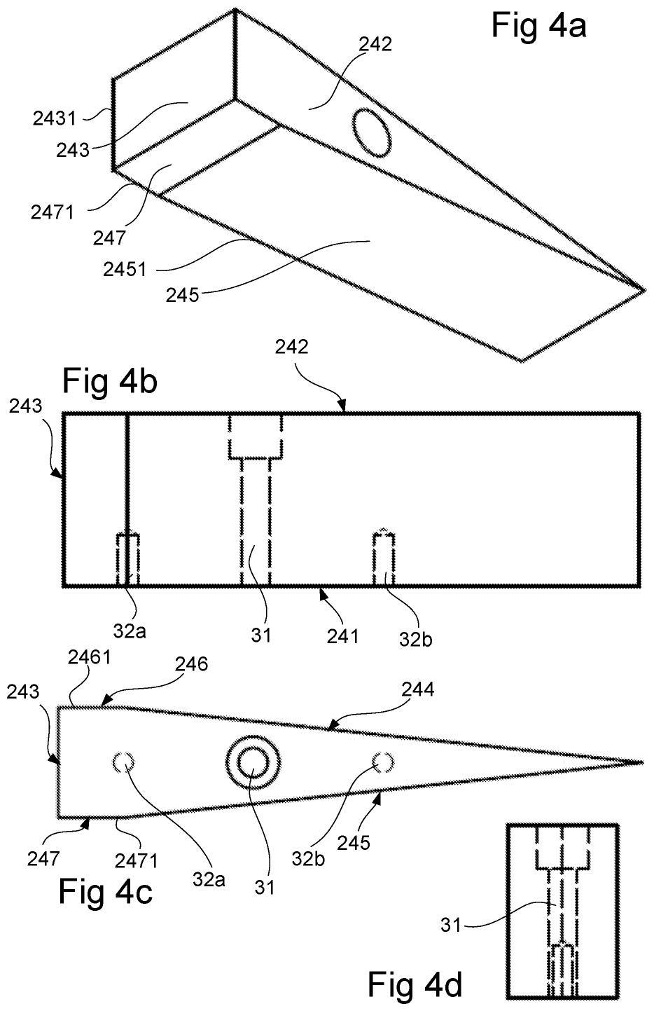

Referring to FIG. 4a-4d, there is illustrated a wedge member according to a first embodiment.

FIG. 4a is a schematic perspective view of the wedge member 24. FIG. 4b is a side elevational view taken in a plane parallel with the flow direction F. FIG. 4c is a top view of the wedge member 24 and FIG. 4d is an elevational view of the wedge member 24 as seen in a direction towards the rear surface 243.

The wedge member 24 is formed with a body portion having the form of a right prism with a base surface that is symmetric about a vertical plane parallel with the flow direction F.

The wedge member thus has a first base surface 241 and a second base surface 242, opposite of the first base surface 241. The base surfaces 241, 242 may be substantially planar and parallel with each other, as illustrated. In further embodiments, the base surfaces 241 may present varying topography, and may in particular diverge from each other as seen in the downstream direction F.

The base surface 241, 242 is defined by a rear side 2431, a pair of taper sides 2441, 2451 and a pair of optional longitudinal sides 2461, 2471.

The rear side 2431 defines the rear wall 243; the taper sides 2441, 2451 define the taper walls 244, 245 and the longitudinal sides 2461, 2471 define the longitudinal walls 246, 247.

The longitudinal sides 2461, 2471, if any, may be shorter than the taper sides 2441, 2451. In particular, the longitudinal sides 2461, 2471 may have a length along the flow direction F which is less than 50% of a length of the taper sides, preferably less than 25% or less than 15%.

The taper sides 2441, 2451 may be symmetric with respect to the rear side 2431. Preferably, each taper side provides a taper angle of less than 8 degrees, preferably less than 7 or about 6 degrees with respect to the flow direction F.

An attachment device may be provided in the wedge member. In the illustrated example, the attachment device comprises a countersunk through hole 31, extending perpendicular to the base surfaces.

Further alignment holes 32a, 32b may also be provided.

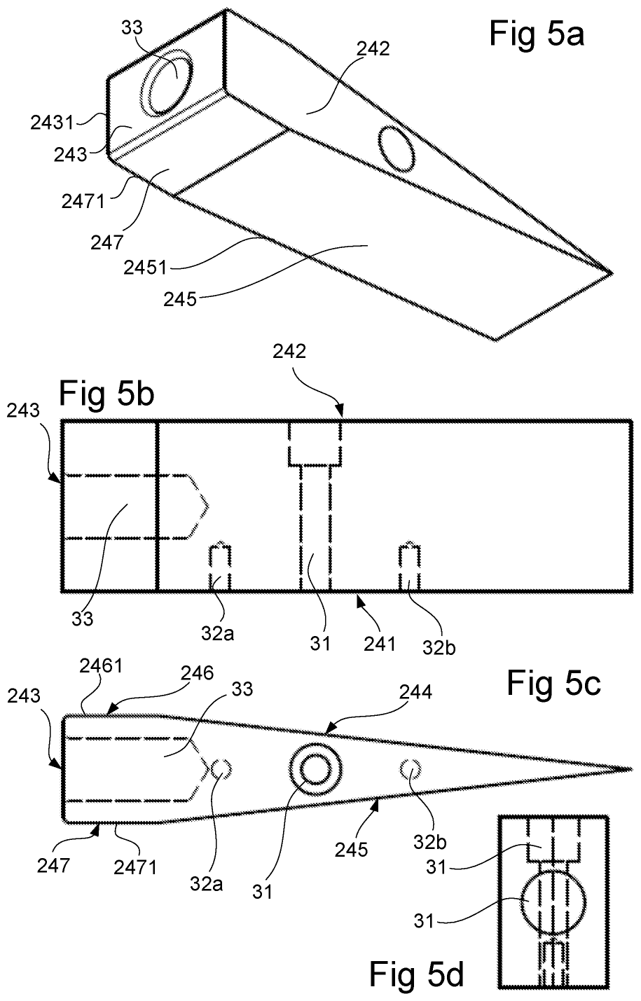

FIGS. 5a-5e schematically illustrate another embodiment of the wedge member. The wedge member illustrated in FIGS. 5a-5e differs from that of FIGS. 4a-4d in that its rear surface 243 presents a recess 33.

The recess 33 may extend from the rear surface 243 perpendicularly into the wedge member body. Thus, the recess may extend between 3 and 40% of a length of the wedge member body, as seen in the downstream direction F, preferably 10-30%.

The recess 33 may have a circular cross section, a diameter of which may be on the order of 50-90%, preferably 60-80%, of a width of the wedge member 24 (i.e. of a length of the rear side 2431).

FIG. 5e schematically illustrates a gas inlet device 21 as seen in a vertical cross sectional plane containing the flow direction F.

As illustrated in FIG. 5e, an extension of the gas orifice 210 may extend into the recess 33, such that the flow of gas impinges on the inside of the recess, thereby changing (possibly reversing) direction, and then changing direction again against the back wall 233 of the niche 23.

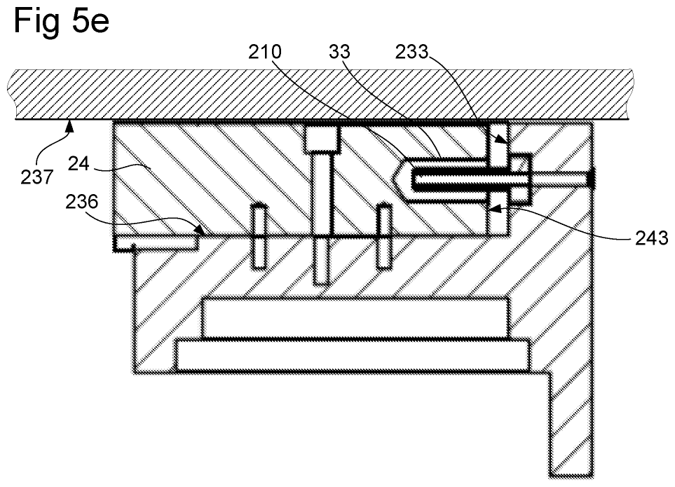

FIG. 6 is a schematic cross sectional view of a gas inlet device 21, illustrating a more general aspect of the gas inlet device according to present disclosure. The gas inlet device 21 has a proximal portion 211 at the rear wall 233 of the niche 23 and a distal portion 212 at an opening of the niche 23.

In the device illustrated in FIG. 6, a gas source 221 is connected to the gas inlet device through a gas inlet control device 22, which is connected to an orifice 210, which in the illustrated embodiment is flush with the back wall 233 of the niche 23. Optionally, the orifice may extend out of the back wall 233 and further optionally, it may extend into a recess 33 in the rear wall 243 of the wedge member.

A flow gap 213 is formed between the side wall 234, 235 and the taper surface 244, 245. The flow gap 213 present at least one portion at which a flow area of the flow gap gradually increases along the downstream direction F.

In the illustrated example, the flow gap 213 presents an upstream portion, throughout which the flow area is substantially constant; a central portion, wherein an opening angle is equal to a taper angle of the taper surface 244, 245 of the wedge member, i.e. about 6-8 degrees; and a downstream portion, wherein an opening angle is equal to the sum of the taper angles of the taper surface 244, 245 of the wedge member and of the taper surface 2342 of the side wall, i.e. about 12-16 degrees.

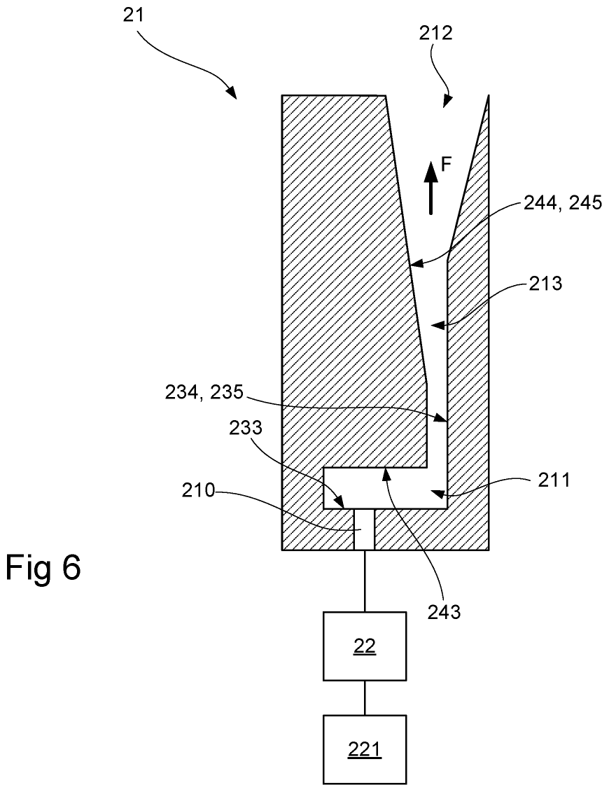

FIG. 7a schematically illustrates a wedge member 21 received in a niche, as seen from the opening portion of the niche.

FIG. 7b schematically illustrates an 1×5 array of five wedge members 21a-21e, separated by divider walls 25a-25d, as seen from the opening portions of the niches.

FIG. 7c schematically illustrates a 3×5 array of 15 wedge members 21a-21e, separated by divider walls 25a-25d, as seen from the opening portions of the niches. Moreover, each pair of adjacent horizontal rows of wedge members is separated by a divider plate 26. Portions of the divider plates closest to the opening of the niches may have tapering plate thickness, analogous with the divider walls. At intersections between divider walls and divider plates, corresponding taper intersections may be provided, as hinted in the drawing.

It is noted that the base surfaces of the wedge members 24 may be formed so as to follow the tapers of the divider plates 26.

Alternatively, the tapers of the divider plates 26 may commence downstream of the edge of the divider walls 25, 25a-25d.

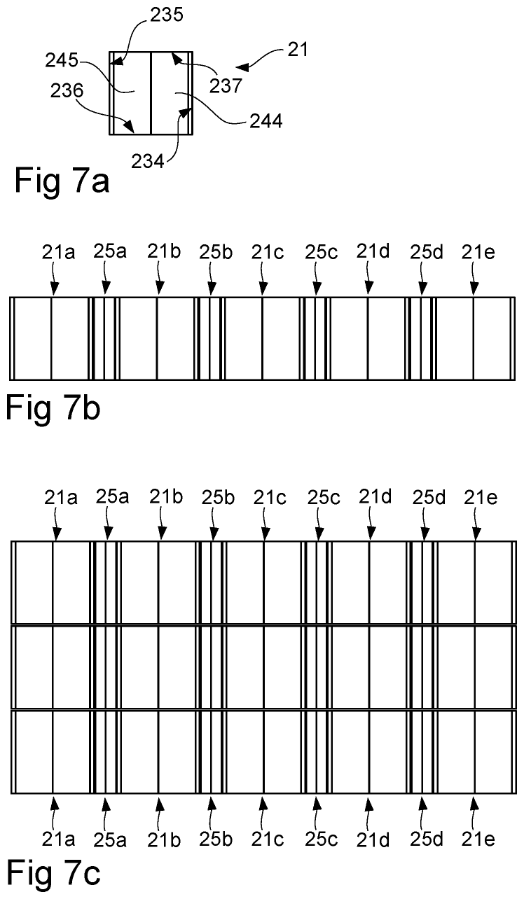

FIGS. 8a-8c illustrate, analogously with FIGS. 7a-7c, an embodiment with a wedge member having the form of a pyramid, with the rear surface 243 as a base. Hence, as illustrated in FIG. 8a, there are not only laterally oriented taper surfaces 244, 245, but also upwardly and downwardly oriented taper surfaces 248, 249.

FIG. 8b schematically illustrates an 1×5 array of gas inlet devices 21a-21e having such pyramid-shaped wedge members.

FIG. 8c schematically illustrates a 3×5 array of gas inlet devices 21a-21e having such pyramid-shaped wedge members.

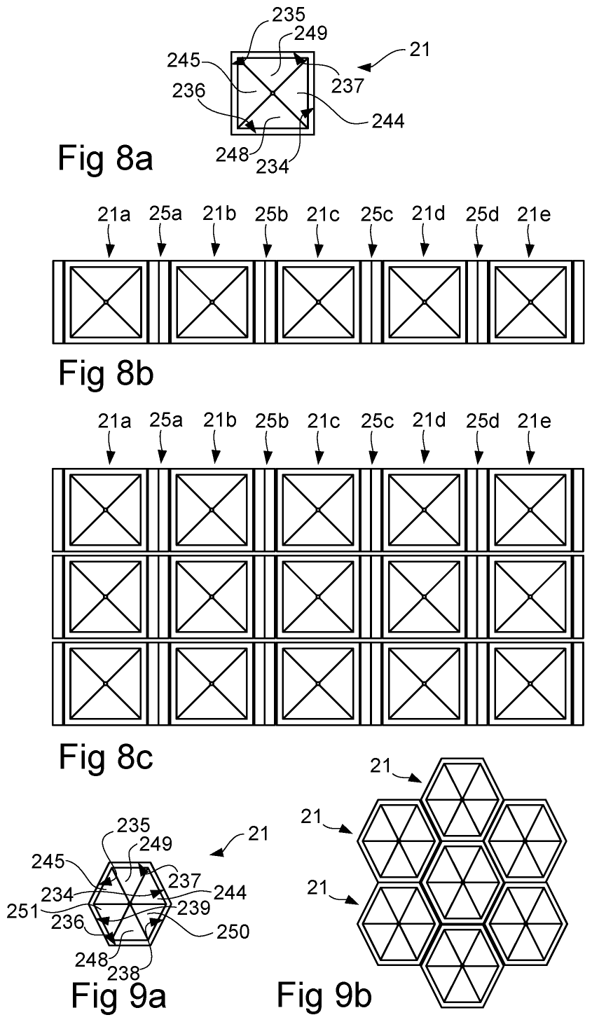

FIGS. 9a-9b schematically illustrates a further development of a gas inlet device 21 with a wedge member having the form of a pyramid with a hexagonal base. This wedge member thus present six taper surfaces 244, 245, 248, 249, 250, 251, top and bottom walls 235, 235 and four side walls 234, 235, 238, 239.

As illustrated in FIG. 9b, such hexagonal gas inlet devices are particularly useful for providing 2D arrays of multiple gas inlet devices, which may be applicable for applications where it is desirable to provide a controlled laminar flow through a channel having e.g. a circular or oval cross section.

Another application for the embodiments in FIGS. 9a-9b and also for the embodiments in FIGS. 7c and 8c, is the use in a so-called showerhead type gas inlet device, where gas is introduced in a direction perpendicular to a substrate surface that is to be treated. Typically, such a gas inlet device would be positioned vertically above the substrate.

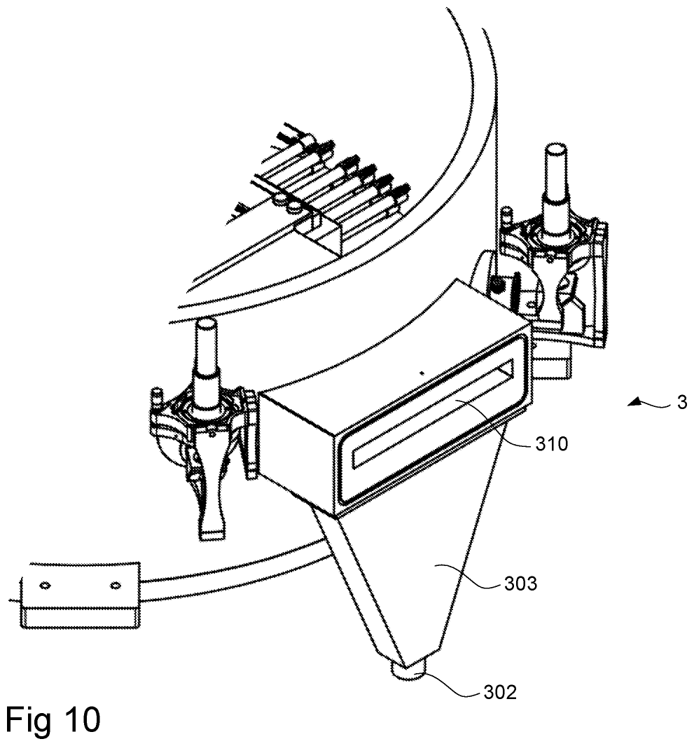

FIG. 10 is a schematic detail view of a portion of the reactor 1, focusing on the gas outlet device 3.

The gas outlet device comprises an upstream portion 301, which has a flow area that is constant and sized and shaped to correspond to a flow area of the gas treatment portion of the reactor, i.e. of the portion of the reactor where the substrate is being treated. Hence, the upstream portion 301 provides a smooth transition to the gas treatment portion by not substantially changing the flow area. Consequently, no or negligible impact on the flow speeds across the gas treatment portion is provided.

The gas outlet device further comprises a downstream portion 302, which has a smaller flow area than the upstream portion. For example, the downstream portion may have a flow area that is 1-10% of the upstream portion.

A transition portion 303, connects the upstream portion and the downstream portion, and has a gradually diminishing flow area.

The transition portion may open to the upstream portion through a downwardly limiting surface of the upstream portion or through an upwardly limiting surface of the upstream portion.

The upstream portion may have a length corresponding to about 10-30% of a total flow path length from the gas inlet device to start of the transition portion

The upstream portion provides a first flow direction, which is substantially parallel with a flow direction in the gas treatment portion of the reactor. The downstream portion provides a second flow direction which presents an angle of 30-90 degrees, preferably 60-90 degrees, to the first flow direction, as seen in a vertical plane parallel with the first flow direction.

In the transition portion the flow area may gradually diminish, by having transition portion walls which taper as seen in at least one plane. The taper may be linear, with a total taper angle of the flow area being about 30-60 degrees, preferably 40-50 degrees.

For example, in the transition portion, a flow area width can be approximated by the expression: W_{F}=Wᵢₙᵢₜ−2×IF tan(γ), wherein Wᵢₙᵢₜ is the width at the upstream portion of the gas outlet device, IF is a length from an upstream start of the transition portion, and γ is a taper angle of the flow area in the transition portion, and wherein, in the transition portion, the width diminishes by less than twice the length IF.

The upstream portion may comprise a feed opening 310, which provides a straight path from an exterior hatch to the gas treatment portion of the reactor.

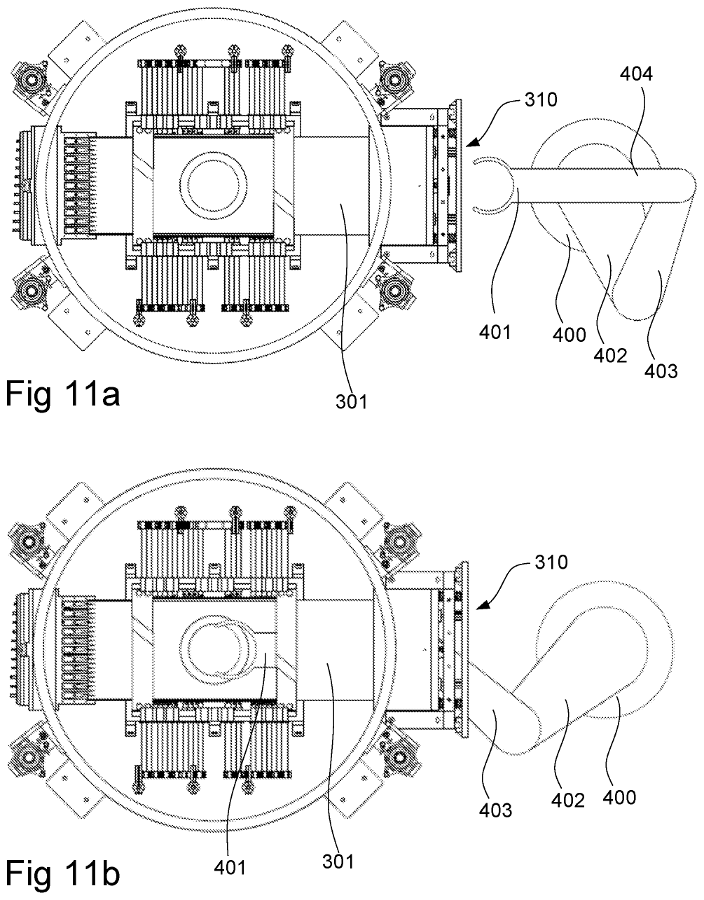

FIGS. 11a-11b schematically illustrate the loading/unloading access to the reactor. A robot 400-404 may be used for loading/unloading the reactor through the opening 310. Normally, the reactor 1 and the robot 400-404 will be arranged in a vacuum environment, e.g. by being positioned in housings 501, 502 which are in communication with each other, such that they will be surrounded by the same pressure (or rather vacuum).

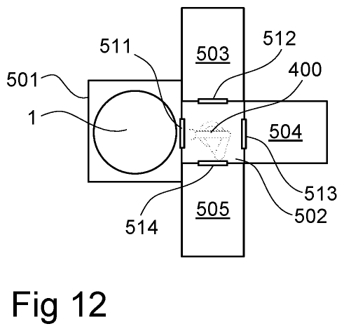

Referring to FIG. 12, a first air lock 511 may be used to separate a reactor housing 501 from a robot housing 502. A second airlock 503 may be used to separate the robot housing 502 from a loading housing 503. Further airlocks 513, 514 may be used to separate the robot housing 502 from further housings 504, 505. For example, a pre-heating housing 504 and a cooling housing 505 may be provided.

The robot may comprise a fixed base 400, a first arm 402, a proximal portion of which being rotatably connected to the base 400; a second arm 403, a proximal portion of which being rotatably connected to a distal portion of the first arm 402; and a third arm 404, a proximal portion of which being rotatably connected to a distal portion of the second arm 403 and a distal portion of which having a gripping device 401 adapted for releasably gripping the substrate 20.

The first and second arms 402, 403 may be configured to move so that the third arm 404 is oriented substantially parallel with the flow direction in the upstream portion of the gas outlet device 3 throughout its movement through the opening 310, to the substrate table 4 and back.

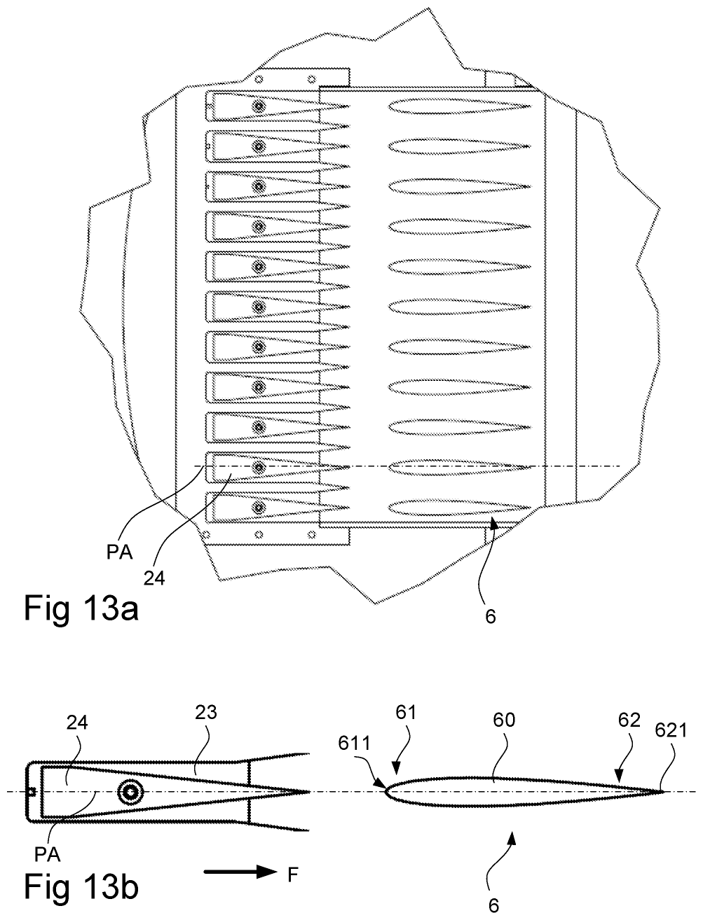

Referring to FIG. 13a-13b, there is illustrated a mixing device 6, for enhancing the mixing of gases introduced through different gas inlet devices.

The mixing device comprises a body 60 having a substantially constant cross section over a height or width of an associated inlet niche.

A base surface of the body, defining the cross section, is elongate along the downstream direction F, and comprises an upstream portion 61 and a downstream portion 62. The upstream portion 61 extends upstream from a point where a base surface width is at its maximum and the downstream portion 62 extends downstream from the point where the base surface width is at its maximum.

A length, along the downstream direction, of the downstream portion 62 is greater than a length of the upstream portion 61. Typically, the downstream portion length may be on the order of 2-5 times the length of the length of the upstream portion.

The upstream portion may present a generally convex surface 611, which faces the upstream direction.

The downstream portion 62 may taper in width towards the downstream direction, such that the downstream portion presents an edge 621, which faces the downstream direction.

The body 60 may be symmetric about a plane PA parallel with the downstream direction.

Hence, the body 60 may have the general cross section of extended drop.

In the example illustrated in FIG. 13a-13b, the symmetry plane PA of the mixing device body is aligned with a symmetry plane of the wedge member 24.

In the case where there is no symmetric wedge member 24, the symmetry plane of the mixing device body may instead be aligned with a central line of the inlet niche 23.

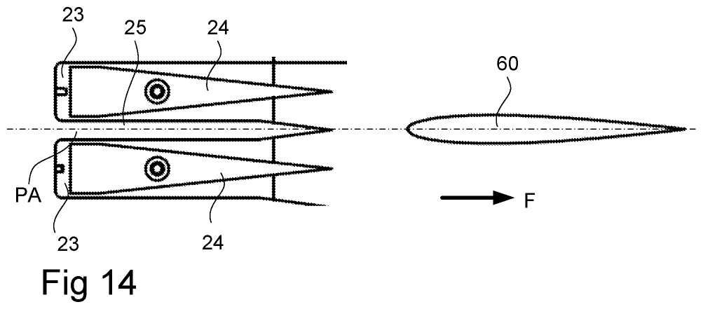

In an alternative embodiment, which is illustrated in FIG. 14, the symmetry plane PA of the mixing device body 60 may be aligned with a symmetry plane PA of a divider wall 25.

In the case where there is no symmetric divider wall 25, the symmetry plane of the mixing device body may instead be aligned with a central line of a divider wall.

1. A gas inlet device for use in a reactor for gas treatment of a substrate, comprising:
an inlet niche having a back wall, and a side wall extending in a downstream direction from the back wall towards an inlet niche opening,
an impingement surface,
a gas orifice, which is configured to direct a gas flow towards the impingement surface, and
a taper surface, extending downstream of the impingement surface, such that a flow gap having, along the downstream direction, gradually increasing cross sectional area, is formed between the side wall and the taper surface.

2. The gas inlet device as claimed in claim 1, wherein the impingement surface is perpendicular±10 degrees, preferably ±5 degrees, to the gas flow directed by the gas orifice.

3. The gas inlet device as claimed in claim 1, wherein a gas orifice opening is flush with the back wall.

4. The gas inlet device as claimed in claim 1, wherein a gas orifice opening extends out of back wall towards the impingement surface.

5. The gas inlet device as claimed in claim 1, wherein the impingement surface presents a recess.

6. The gas inlet device as claimed in claim 5, wherein the gas orifice extends into the recess.

7.-12. (canceled)

13. The gas inlet device as claimed in claim 1, further comprising a throttling arrangement, which is configured such that a gas flow of the gas inlet is adjustable between a maximum flow and a minimum flow.

14. The gas inlet device as claimed in claim 1, wherein the niche presents a pair of opposing walls and wherein the taper surface and the side wall extend completely between said opposing walls.

15. The gas inlet device as claimed in claim 14, wherein the flow gap presents a rectangular cross section, defined by the opposing walls, the taper surface and the side wall.

16. The gas inlet device as claimed in claim 14, wherein the gas inlet device is formed by the niche and a wedge member, which is received in the niche, such that a short side of the wedge member provides the impingement surface.

17. The gas inlet device as claimed in claim 16, wherein the niche presents a pair of side walls, and wherein the wedge member is spaced from both side walls, such that flow gaps are formed on both sides of the wedge member.

18.-21. (canceled)

22. The gas inlet device as claimed in claim 1, wherein the niche presents at least two juxtaposed side wall portions, that extend at an angle to each other of 50 degrees, and at least two juxtaposed taper surfaces, which extend at an angle to each other of 50 degrees.

23. The gas inlet device as claimed in claim 1, wherein the gas inlet device is formed by the niche and a wedge member, which is received in the niche, such that a short side of the wedge member provides the impingement surface.

24.-30. (canceled)

31. A gas inlet array comprising a plurality of m×n gas inlet devices as claimed in claim 1, wherein m≥1 and n≥2.

32.-46. (canceled)

47. A reactor for gas treatment of a substrate, in particular for forming an epitaxial layer through a chemical vapor deposition process, comprising a gas inlet array comprising a plurality of m×n gas inlet devices as claimed in claim 1.

48.-61. (canceled)
